(19) United States
(12) Patent Application Publication
(10) Pub. No.: US 2020/0194462 A1
(43) Pub. Date: Jun. 18, 2020

(54) THIN FILM TRANSISTOR SUBSTRATE AND METHOD OF PRODUCING THIN FILM TRANSISTOR SUBSTRATE

(71) Applicant: SHARP KABUSHIKI KAISHA, Sakai City (JP)

(72) Inventor: KAZUYA NAKAJIMA, Sakai City (JP)

(21) Appl. No.: 16/711,444

(22) Filed: Dec. 12, 2019

Related U.S. Application Data
(60) Provisional application No. 62/781,363, filed on Dec. 18, 2018.

(51) Int. Cl. H01L 27/12; H01L 29/786; G02F 1/1368; G02F 1/1362

(52) U.S. Cl. CPC H01L 27/124; H01L 27/1288; G02F 1/136286; G02F 1/1368; H01L 29/786

(57) ABSTRACT

A thin film transistor substrate includes a pixel electrode that is a section of a conductive film, an insulating film disposed on the conductive film, a TFT including a channel section that is a section of a semiconductor film disposed on the insulating film, a source electrode including a semiconductor source section that is a section of the semiconductor film and connected to one end of the channel section and a metal source section that is a section of a metal film disposed above the semiconductor film, and a drain electrode including a semiconductor drain section that is a section of the semiconductor film and connected to another end of the channel section and a metal drain section that is a section of the metal film and overlaps the semiconductor drain section and extends from the semiconductor drain section to overlap and to be connected to the pixel electrode.

### CROSS REFERENCE TO RELATED APPLICATION

This application claims priority from U.S. Provisional Patent Application No. 62/781,363 filed on Dec. 18, 2018. The entire contents of the priority application are incorporated herein by reference.

### TECHNICAL FIELD

The technology described herein relates to a thin film transistor substrate and a method of producing the thin film transistor substrate.

### BACKGROUND ART

A thin film transistor substrate included in a liquid crystal display device is disclosed in Japanese Unexamined Patent Application Publication No. 2005-181984 and Japanese Unexamined Patent Application Publication No. 2012-164976, and the thin film transistor substrate includes a thin film transistor. The thin film transistor substrate includes a conductive film for forming pixel electrodes, a semiconductor film and a metal film for forming the thin film transistor, and an insulating film disposed on top of each other in sequence in a pixel region on a substrate. Therefore, a number of photomasks are used in the producing process and a number of photolithography steps are necessary. This increases a production cost and lowers productivity. Japanese Unexamined Patent Application Publication No. 2005-181984 and Japanese Unexamined Patent Application Publication No. 2012-164976 disclose that multi-gradation masks such as half-tone masks are used to reduce the number of photomasks.

However, the thin film transistor substrate and the method of producing the same described in the patent documents may be improved more in respect of reduction of the number of photomasks.

### SUMMARY

The technology described herein was made in view of the above circumstances. An object is to reduce the number of photomasks used in producing a thin film transistor substrate.

An embodiment of the technology described herein is a thin film transistor substrate including a thin film transistor. The thin film transistor substrate includes a pixel electrode that is a section of a conductive film, an insulating film disposed in a layer upper than the conductive film and formed to expose the pixel electrode, a channel section that is a section of a semiconductor film disposed on the insulating film and that is included in the thin film transistor, a source electrode included in the thin film transistor, and a drain electrode included in the thin film transistor. The source electrode includes (a-1) a semiconductor source section that is a section of the semiconductor film and connected to one end of the channel section and (a-2) a metal source section that is a section of a metal film disposed in a layer upper than the semiconductor film, the semiconductor source section and the metal source section being disposed on top of each other. The drain electrode includes (b-1) a semiconductor drain section that is a section of the semiconductor film and connected to another end of the channel section and (b-2) a metal drain section that is a section of the metal film and overlaps the semiconductor drain section and extends from the semiconductor drain section so as to overlap the pixel electrode and is connected to the pixel electrode.

An embodiment of the technology described herein is a method of producing a thin film transistor substrate including a thin film transistor. The method includes a conductive film forming step of forming a conductive film, an insulating film forming step of forming an insulating film in a layer upper than the conductive film, a semiconductor film forming step of forming a semiconductor film in a layer upper than the insulating film, a hole forming step, a semiconductor film patterning step, a metal film forming step, and a metal film patterning step. The hole forming step is for forming a hole through which a section of the conductive film is exposed as a pixel electrode by patterning a photoresist film in a predetermined form on the semiconductor film while using a multi-gradation mask including sections having different light transmittance and etching portions of the insulation film and the semiconductor film while using a patterned photoresist film as an etching mask. The semiconductor film patterning step is for developing and removing a portion of the photoresist film that is patterned in the hole forming step and etching a portion of the semiconductor film while using the photoresist film a portion of which is removed as an etching mask to provide a channel section, a semiconductor source section connected to one end of the channel section, and a semiconductor drain section connected to another end of the channel section from the semiconductor film. The metal film forming step is for forming a metal film disposed in a layer upper than the semiconductor film after the semiconductor film patterning step. The metal film patterning step is for patterning a photoresist film in a predetermined form on the metal film while using the multi-gradation mask in a position different from a position used in the hole forming step and etching a portion of the metal film while using a patterned photoresist film as an etching mask to provide a source electrode by disposing a metal source section in a layer upper than the semiconductor source section and provide a drain electrode by disposing a metal drain section in a layer upper than the semiconductor drain section while being displaced from the semiconductor drain section such that one end of the metal drain section projects toward the hole and overlaps a section of the conductive film.

According to the technology described herein, the number of photomasks used in producing a thin film transistor substrate can be reduced.

### BRIEF DESCRIPTION OF THE DRAWINGS

FIG. 1 is a plan view of a liquid crystal panel including a thin film transistor substrate according to one embodiment.

FIG. 2 is a cross-sectional view schematically illustrating the liquid crystal panel illustrated in FIG. 1.

FIG. 3 is a plan view schematically illustrating a configuration of an array substrate, which is the thin film transistor substrate according to the embodiment, in a display area.

FIG. 4A is a cross-sectional view along line A-A in FIG. 3.

FIG. 4B is a cross-sectional view along line B-B in FIG. 3.

FIG. 4C is a cross-sectional view along line C-C in FIG. 3.

FIG. 4D is a cross-sectional view along line D-D in FIG. 3.

FIG. 5 is a plan view illustrating a state after a first photolithography process.

FIG. 6A is a cross-sectional view along line A-A in FIG. 5.

FIG. 6B is a cross-sectional view along line B-B in FIG. 5.

FIG. 6C is a cross-sectional view along line C-C in FIG. 5.

FIG. 6D is a cross-sectional view along line D-D in FIG. 5.

FIG. 7A is a plan view illustrating a portion of a second photomask.

FIG. 7B is a plan view schematically illustrating the second photomask that is used in a second photolithography process.

FIG. 7C is a plan view schematically illustrating the second photomask that is used in a third photolithography process.

FIG. 8A is a cross-sectional view taken along line A-A and illustrating a state after a photoresist forming step included in the second photolithography process.

FIG. 8B is a cross-sectional view taken along line B-B and illustrating a state after the photoresist forming step included in the second photolithography process.

FIG. 8C is a cross-sectional view taken along line C-C and illustrating a state after the photoresist forming step included in the second photolithography process.

FIG. 8D is a cross-sectional view taken along line D-D and illustrating a state after the photoresist forming step included in the second photolithography process.

FIG. 9A is a cross-sectional view taken along line A-A and illustrating a state after an ashing step included in the second photolithography process.

FIG. 9B is a cross-sectional view taken along line B-B and illustrating a state after the ashing step included in the second photolithography process.

FIG. 9C is a cross-sectional view taken along line C-C and illustrating a state after the ashing step included in the second photolithography process.

FIG. 9D is a cross-sectional view taken along line D-D and illustrating a state after the ashing step included in the second photolithography process.

FIG. 10 is a plan view illustrating a state after the second photolithography process.

FIG. 11A is a cross-sectional view along line A-A in FIG. 10.

FIG. 11B is a cross-sectional view along line B-B in FIG. 10.

FIG. 11C is a cross-sectional view along line C-C in FIG. 10.

FIG. 11D is a cross-sectional view along line D-D in FIG. 10.

FIG. 12 is a plan view illustrating a state after a pixel electrode forming process.

FIG. 13A is a cross-sectional view along line A-A in FIG. 12.

FIG. 13B is a cross-sectional view along line B-B in FIG. 12.

FIG. 13C is a cross-sectional view along line C-C in FIG. 12.

FIG. 13D is a cross-sectional view along line D-D in FIG. 12.

FIG. 14A is a cross-sectional view illustrating a state after an ashing step included in a third photolithography process taken along line A-A.

FIG. 14B is a cross-sectional view illustrating a state after the ashing step included in the third photolithography process taken along line B-B.

FIG. 14C is a cross-sectional view illustrating a state after the ashing step included in the third photolithography process taken along line C-C.

FIG. 14D is a cross-sectional view illustrating a state after the ashing step included in the third photolithography process taken along line D-D.

FIG. 15 is a plan view illustrating a state after the third photolithography process.

FIG. 16A is a cross-sectional view along line A-A in FIG. 15.

FIG. 16B is a cross-sectional view along line B-B in FIG. 15.

FIG. 16C is a cross-sectional view along line C-C in FIG. 15.

FIG. 16D is a cross-sectional view along line D-D in FIG. 15.

FIG. 17 is a plan view illustrating a state after the third photolithography process included in a method of producing a thin film transistor substrate according to a modified embodiment.

FIG. 18A is a cross-sectional view along line A-A in FIG. 17.

FIG. 18B is a cross-sectional view along line B-B in FIG. 17.

FIG. 18C is a cross-sectional view along line C-C in FIG. 17.

FIG. 18D is a cross-sectional view along line D-D in FIG. 17.

FIG. 19A is a cross-sectional view of the thin film transistor substrate according to the modified embodiment taken along line A-A.

FIG. 19B is a cross-sectional view of the thin film transistor substrate according to the modified embodiment taken along line B-B.

FIG. 19C is a cross-sectional view of the thin film transistor substrate according to the modified embodiment taken along line C-C.

FIG. 19D is a cross-sectional view of the thin film transistor substrate according to the modified embodiment taken along line D-D.

FIG. 20A is a cross-sectional view taken along line A-A and illustrating a state in which a photoresist film for etching two metal films is formed in the method of producing a thin film transistor substrate according to another modified embodiment.

FIG. 20B is a cross-sectional view taken along line B-B and illustrating a state in which the photoresist film for etching the two metal films is formed in the method of producing a thin film transistor substrate according to another modified embodiment.

FIG. 20C is a cross-sectional view taken along line C-C and illustrating a state in which the photoresist film for etching the two metal films is formed in the method of producing a thin film transistor substrate according to another modified embodiment.

FIG. 20D is a cross-sectional view taken along line D-D and illustrating a state in which the photoresist film for etching the two metal films is formed in the method of producing a thin film transistor substrate according to another modified embodiment.

### DETAILED DESCRIPTION

Embodiments will be described with reference to the drawings in detail as embodiments for carrying out the present technology. The present technology is not necessarily limited to the following embodiments but may be carried out in various embodiments with modifications or improvement based on knowledges of those who have skills in the art.

<Configuration of Liquid Crystal Panel>

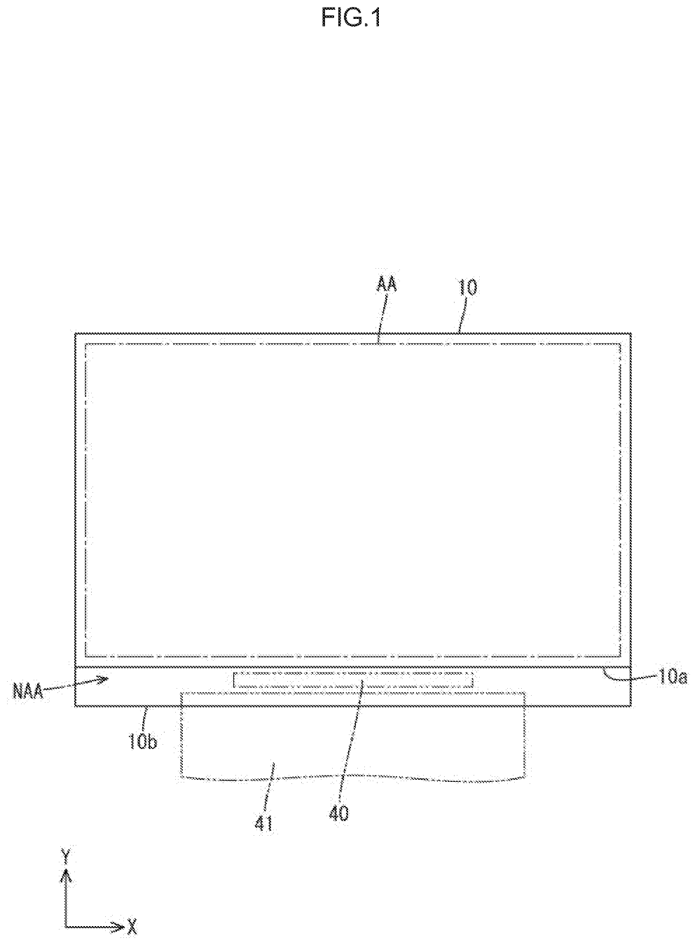

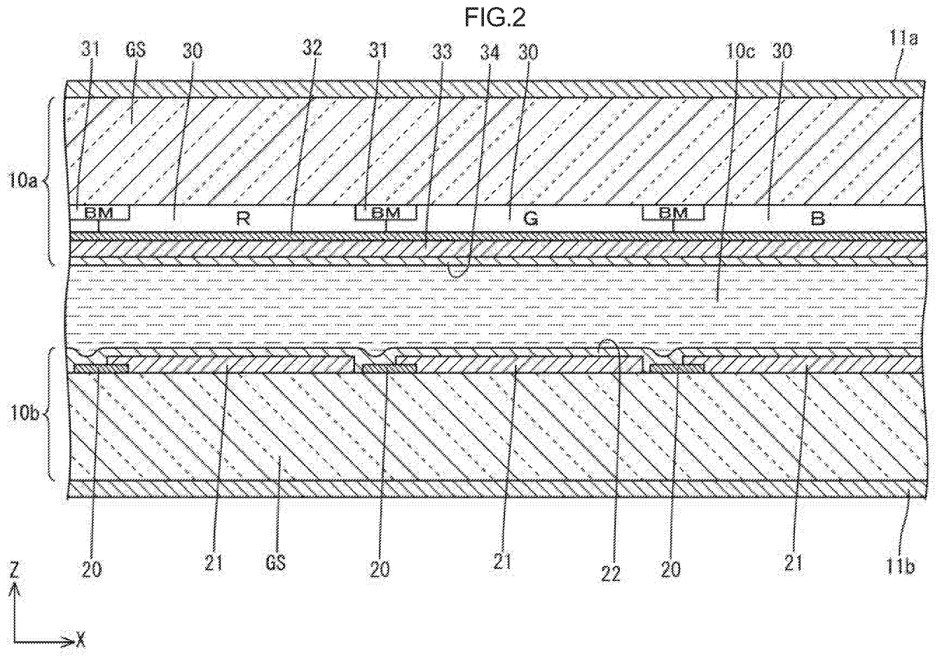

A liquid crystal panel 10 including a thin film transistor substrate according to one embodiment is illustrated in FIG. 1. The liquid crystal panel 10 has a laterally elongated quadrangular overall shape. The liquid crystal panel 10 has a display surface that is divided into a display area AA (an active area) where an image is displayed and a non-display area NAA (a non-active area) where no image is displayed. The non-display area NAA has a frame shape surrounding the display area AA. In FIG. 1, an outline of the display area AA is illustrated with a chain line and an area outside the chain line is the non-display area NAA. X-axes, Y-axes, and Z-axes may be present in the drawings. The axes in each drawing correspond to the respective axes in other drawings. In the liquid crystal panel 10, a long-side direction corresponds to an X-axis direction in each drawing and a short-side direction corresponds to a Y-axis direction in each drawing. A vertical direction (a front-rear direction) is defined with reference to FIG. 2 and an upper side and a lower side may be referred to as a front side and a rear side, respectively.

As illustrated in FIG. 2, the liquid crystal panel 10 includes a pair of substrates 10a, 10b and a liquid crystal layer 10c. The substrates 10a, 10b are substantially transparent and highly transmissive and opposed to each other. The liquid crystal layer 10c is disposed between the pair of substrates 10a, 10b and includes liquid crystal molecules that are substances whose optical characteristics are varied according to application of an electric field. The substrates 10a, 10b are bonded with sealing material while having a cell gap of a thickness of the liquid crystal layer 10c. One on a front side (a front surface side) of the pair of substrates 10a, 10b included in the liquid crystal panel 10 is a CF substrate 10a (a counter substrate) and another one on a rear side (a rear surface side) is an array substrate 10b (a TFT substrate, a display substrate, an active matrix substrate). Each of the CF substrate 10a and the array substrate 10b includes a glass substrate GS and various kinds of films that are stacked in layers on an inner surface side of the glass substrate GS. Polarizing plates 11a, lib (see FIG. 2) are bonded to outer surfaces of the respective substrates 10a, 10b.

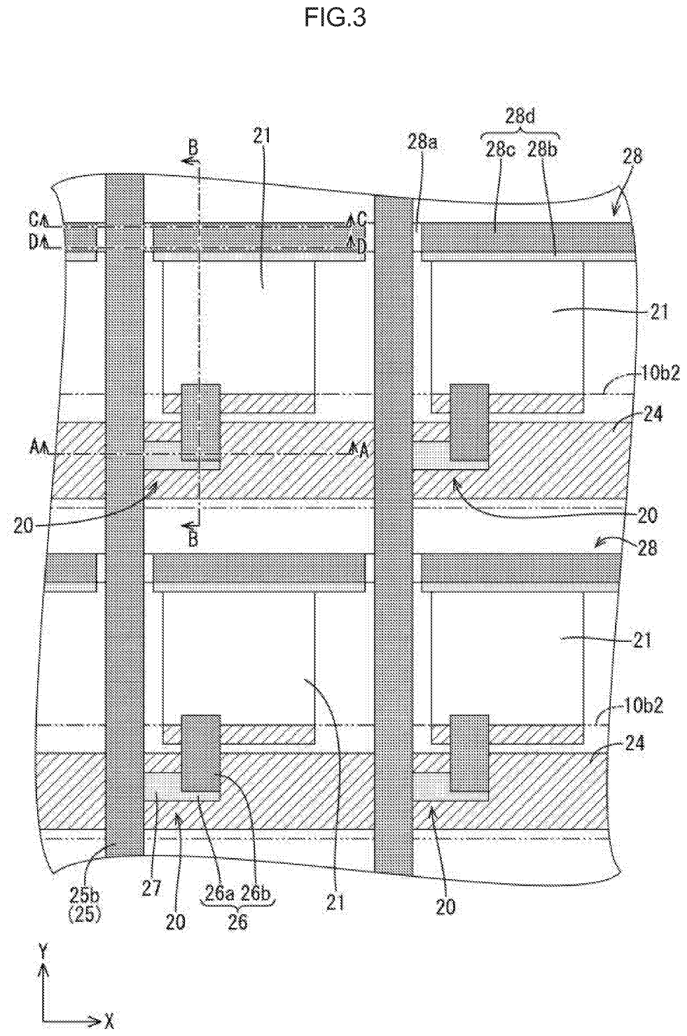

The array substrate 10b, which is one of the substrates 10a, 10b disposed on the rear side, is the thin film transistor substrate of the embodiment. Details will be described later. The thin film transistor substrate includes thin film transistors 20 (TFTs) and pixel electrodes 21 that are connected to the respective TFTs 20 and the TFTs 20 and the pixel electrodes 21 are arranged in a matrix as illustrated in FIG. 3. An alignment film 22 is disposed to cover the TFTs 20 and the pixel electrodes 21. The CF substrate 10a (the counter substrate) disposed on the front side includes color filters 30, a black matrix 31 (a light blocking film), an overcoat film 32, and a counter electrode 33. The color filters 30 include red (R), green (G), and blue (B) color portions in a predefined sequence. The black matrix 31 is disposed between the adjacent color portions. The overcoat film 32 and the counter electrode 33 are disposed to cover the color filters 30 and the black matrix 31 and. The counter electrode 33 is made of transparent conductive material such as indium tin oxide (ITO). An alignment film 34 is disposed to cover the counter electrode 33.

The liquid crystal panel 10 includes a negative-type nematic liquid crystal material as the liquid crystal material included in the liquid crystal layer 10c. In an initial state (no current is supplied) in which no electric field is created between the substrates 10a, 10b, the liquid crystal molecules are aligned substantially vertically with respect to the alignment films 34, 22 that are surfaces of the substrates 10a, 10b. The liquid crystal panel 10 operates in a VA mode.

As illustrated in FIG. 1, the array substrate 10b has a short-side direction (the Y-axis direction) dimension that is longer than that of the CF substrate 10a. The array substrate 10b is bonded to the CF substrate 10a so as to be projected from the CF substrate 10a in the short-side direction. The array substrate 10b includes a non-overlapping portion that is not overlapped with the CF substrate 10a. A driver 40 (a panel driving section) for driving the TFTs 20 in the display area AA is mounted on the non-overlapping portion of the array substrate 10b with the chip-on-glass (COG) technology. A flexible circuit board 41 for transmitting signals related to a display function to the driver 40 is connected to the non-overlapping portion.

<Brief Configuration of Array Substrate>

Next, a configuration of the array substrate 10b, which is the thin film transistor substrate of the present embodiment, will be described in detail. As is described earlier, the array substrate 10b includes the thin film transistors 20 (TFTs), which are switching components, and the pixel electrodes 21. The TFTs 20 and the pixel electrodes 21 are arranged in a matrix along the X-axis direction and the Y-axis direction. Gate lines 24 extending in the X-axis direction and source lines 25 extending in the Y-axis direction are routed in a grid to surround the TFTs 20 and the pixel electrodes 21. The pixel electrodes 21 have a square shape and are arranged in areas surrounded by the gate lines 24 and the source lines 25.

The TFT 20 includes a gate electrode (a portion of the gate line 24), a source electrode (a portion of the source line 25), a drain electrode 26, and a channel section 27. The gate lines 24, which will be described in detail, and the pixel electrodes 21 are included in the lowest layer in the array substrate 10b. Sections of the gate lines 24 (sections overlapping the channel sections 27) function as the gate electrodes. The source electrodes are sections of the source lines 25 and connected to one ends of the channel sections 27. The drain electrodes 26 are spaced from the source lines 25 with respect to the X-axis direction and connected to another ends of the channel sections 27 (opposite side ends from the source electrodes). The drain electrodes 26 are connected to the channel sections 27 at one ends thereof with respect to the X-axis direction (lower ends in FIG. 3) and are connected to the pixel electrodes 21 at another ends thereof (upper ends in FIG. 3). The channel sections 27 overlap the gate lines 24 and extend in the X-axis direction. Two ends of each channel section 27 are coupled to the source line 25 and the drain electrode 26, respectively. When the TFTs 20 are driven based on the scanning signals supplied to the gate lines 24, the data signals (image signals, electric charges) supplied to the source lines 25 are supplied to the drain electrodes 26 via the channel sections 27. As a result, the pixel electrodes 21 are charged with the potentials based on the data signals.

As illustrated in FIG. 2, the counter electrode 33 included in the CF substrate 10a is always supplied with a substantially constant reference electric potential and extends at least a substantially entire area of the display area AA. When a potential difference is created between the pixel electrode 21 and the counter electrode 33 that overlap each other according to charging of the pixel electrode 21, an electric field is created between the substrates 10a, 10b and the alignment state of the liquid crystal molecules included in the liquid crystal layer 10c is controlled.

Further, the array substrate 10b in the present embodiment includes auxiliary capacitance lines 28 that keep the potential of the pixel electrode 21. The auxiliary capacitance lines 28, which will be described in detail later, extend in parallel to the gate lines 24 and are disposed on an opposite side (on an upper side in FIG. 3) with respect to the pixel electrode 21 in the Y-axis direction.

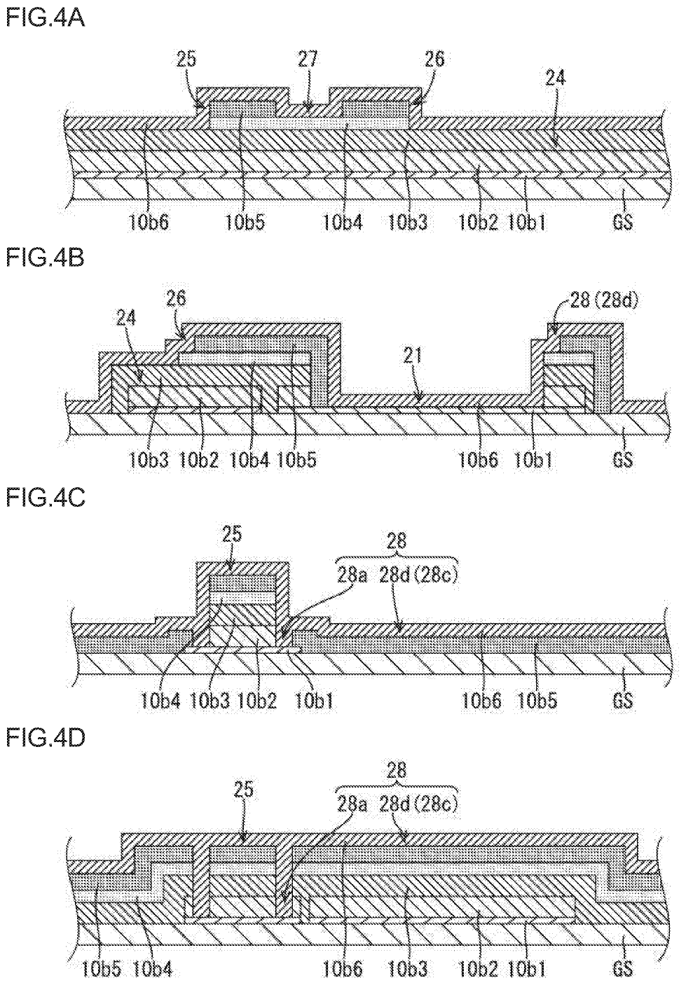

Various kinds of films that are disposed on top of each other on an inner surface of the array substrate 10b will be described. As illustrated in FIGS. 4A to 4D, the array substrate 10b includes a glass substrate GS and various films disposed on top of each other on the glass substrate GS. The various films include a transparent conductive film 10b1 (a conductive film), a first metal film 10b2 (a gate metal film), a first insulating film 10b3, a semiconductor film 10b4, a second metal film 10b5 (a source metal film), and a second insulating film 10b6 disposed in this sequence from a lower side (a glass substrate GS side). The alignment film 22 is disposed on the second insulating film 10b6.

The transparent conductive film 10b1 is made of transparent conductive material (such as indium tin oxide (ITO) and indium zinc oxide (IZO)) and extends over the display area AA and the non-display area NAA and mainly configures the pixel electrodes 21. Each of the first metal film 10b2 and the second metal film 10b5 includes a single-layer film made of one kind metal material selected from a group of Al, Cu, Ti, Mo, a multi-layer film made of different kinds of the metal material, or an alloy to have conductivity and light blocking properties. Each of the films extends over the display area AA and the non-display area NAA. The first metal film 10b2 mainly configures the gate lines 24. The second metal film 10b5 mainly configures the source lines 25 and the drain electrodes 26 of the TFTs 20. The first insulating film 10b3 and the second insulating film 10b6 are made of inorganic material such as silicon nitride (SiNₓ), or silicon oxide (SiO₂) and are disposed between the semiconductor film 10b4 included in an upper layer and the first metal film 10b2 included in a lower layer to isolate them from each other. The second insulating film 10b6 is made of the material same as that of the first insulating film 10b3 and is disposed in a solid pattern to extend the display area AA and the non-display area NAA and cover all of the sections that are included in a lower layer side than the second insulating film 10b6. The semiconductor film 10b4 is a thin film made of amorphous silicon or an oxide semiconductor and the channel sections 27 of the TFTs 20 are sections of the semiconductor film 10b4.

<Method of Producing Array Substrate>

The array substrate 10b, which is a thin film transistor substrate in this embodiment, has characteristics in a stacking structure. With such a stacking structure, the array substrate 10b including the TFTs 20 can be produced with only two photomasks. Hereinafter, the inside structure of the array substrate 10b will be described more in detail for every step of the producing method.

(i) First Photolithography Process

The method of producing the array substrate 10b in this embodiment mainly includes three photolithography processes. The first photolithography process includes a transparent conductive film forming step (a conductive film forming step), a first metal film forming step (a lower layer side metal film forming step), and a transparent conductive film/first metal film etching step (a conductive film/lower layer metal film etching step). The transparent conductive film forming step is forming the transparent conductive film 10b1, which is a conductive film. The first metal film forming step is for forming the first metal film 10b2, which is a lower layer-side metal film, on the transparent conductive film 10b1. The transparent conductive film/first metal film etching step is for etching both of the transparent conductive film 10b1 and the first metal film 10b2.

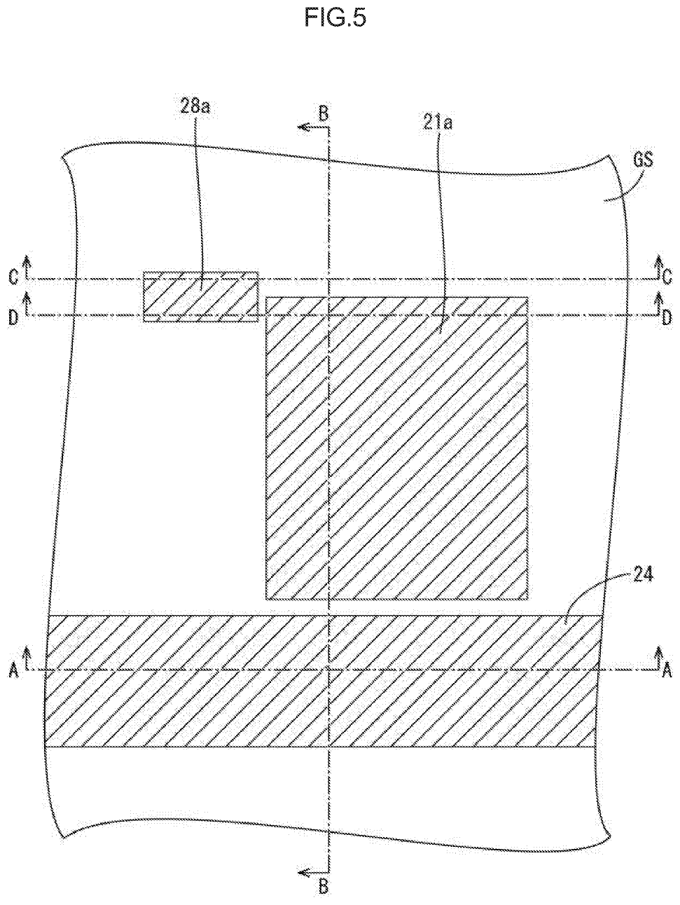

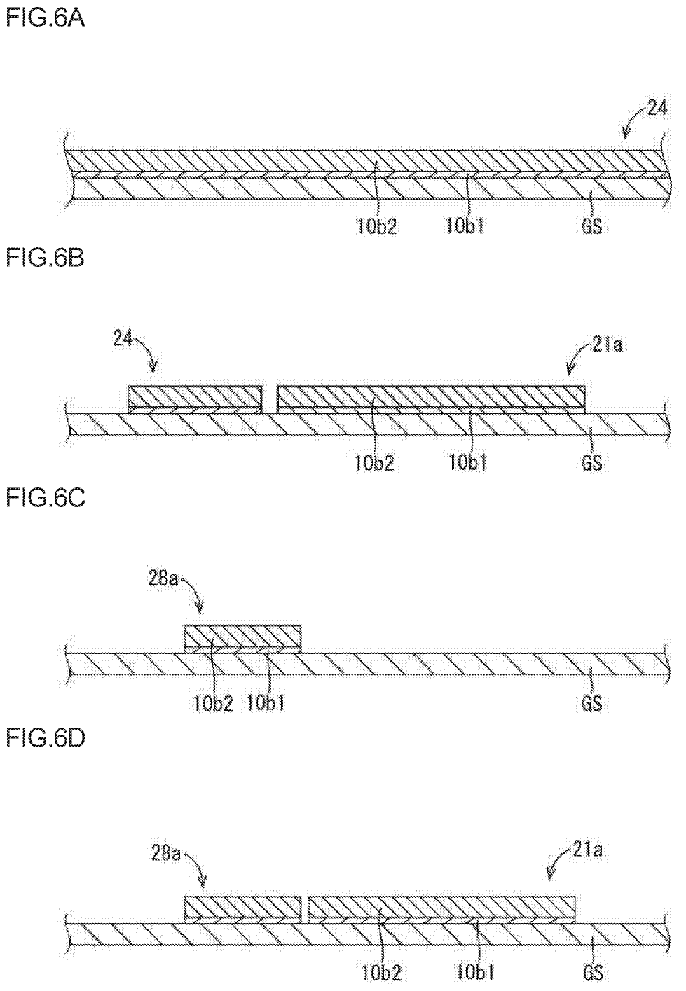

In the first photolithography process, the transparent conductive film 10b1 and the first metal film 10b2 are formed on top of each other via the transparent conductive film forming step and the first metal film forming step. Subsequently, a photoresist is overlaid on the first metal film 10b2 and the photoresist is exposed and developed and a photoresist film is patterned in a predetermined form. Then, the transparent conductive film 10b1 and the first metal film 10b2 are dry-etched or wet-etched using the photoresist film obtained through patterning. Portions of the metal films 10b1, 10b2 on which the photoresist is not overlaid are etched and removed. Portions of the metal films 10b1, 10b2 on which the photoresist is overlaid remain. Accordingly, as illustrated in FIGS. 5 and 6, the gate lines 24, pixel electrode sections 21a including the pixel electrodes 21, and capacitance line connecting sections 28a, which are portions of the auxiliary capacitance lines 28, are formed as sections of the transparent conductive film 10b1 and the first metal film 10b2.

(ii) Second Photolithography Process

Next, the second photolithography process is performed. The second photolithography process includes a first insulating film forming step (an insulating film forming step), a semiconductor film forming step, a photoresist forming step, a first insulating film/semiconductor film etching step, an ashing step, and a semiconductor film etching step. The first insulting film forming step is for forming the first insulating film 10b3 on the first metal film 10b2. The semiconductor film forming step is forming the semiconductor film 10b4 on the first insulating film 10b3. The photoresist forming step is for patterning a photoresist on the semiconductor film 10b4 by exposing and developing the photoresist film while using a second photomask PM. The first insulating film/semiconductor film etching step is for etching the first insulating film 10b3 and the semiconductor film 10b4 while using the photoresist film obtained through patterning as an etching mask. The ashing step is for removing a portion of the photoresist film with ashing. The semiconductor film etching step is for etching the semiconductor film 10b4 while using the photoresist film obtained through ashing as the etching mask.

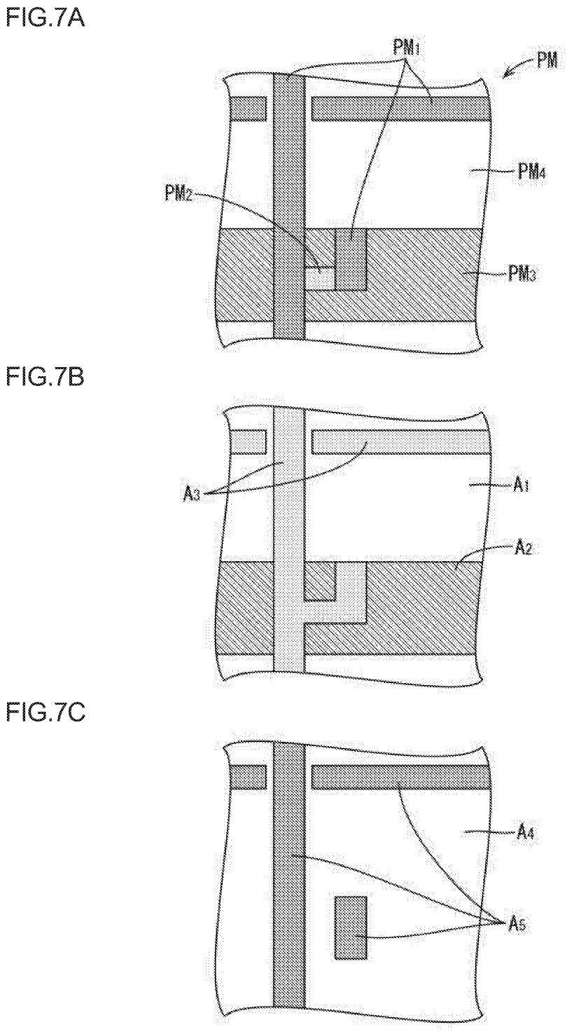

In the second photolithography process, through the first insulating film forming step and the semiconductor film forming step, the first insulating film 10b3 and the semiconductor film 10b4 are formed on top of each other. Subsequently, in the photoresist forming step, the photoresist film is disposed on the semiconductor film 10b4 and the photoresist film is exposed and developed while using the second photomask PM illustrated in FIG. 7A to be patterned.

The second photomask PM is a multi-gradation mask (a half-tone mask or a gray-tone mask). Specifically, in the present embodiment, as illustrated in FIG. 7A, the second photomask PM is divided into four sections PM₁, PM₂, PM₃, PM₄ that have four different light transmittance, respectively. In detail, as is obvious from FIG. 7A and FIG. 3, the first sections PM₁ are sections corresponding to the source line 25, the drain electrode 26, and the auxiliary capacitance line 28. The second section PM₂ is a section corresponds to the channel section 27. The third section PM₃ is a section excluding the first sections PM₁ and the second section PM₂ from a section covering the gate line 24. The fourth section PM₄ is other sections. The first sections PM₁ have lowest light transmittance (transmittance is 0%, light blocking property) and the fourth sections PM₄ have highest light transmittance (transmittance is 100%). The second section PM₂ and the third section PM₃ have light transmittance that is intermediate between that of the first sections PM₁ and that of the fourth section PM₄ and the light transmittance of the third section PM₃ is higher than that of the second section PM₂.

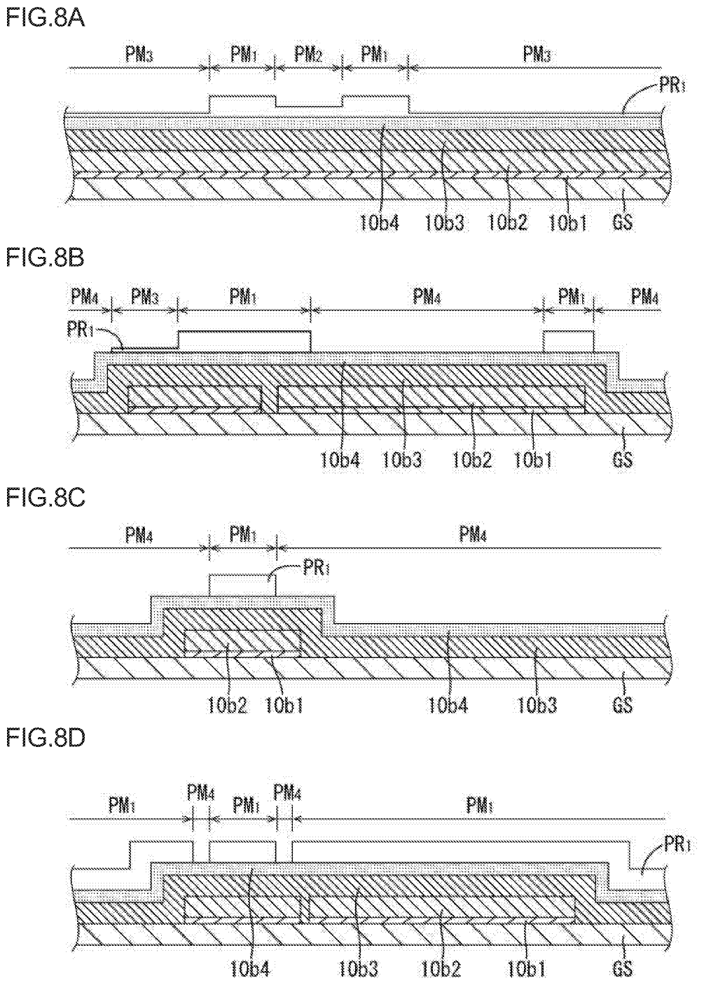

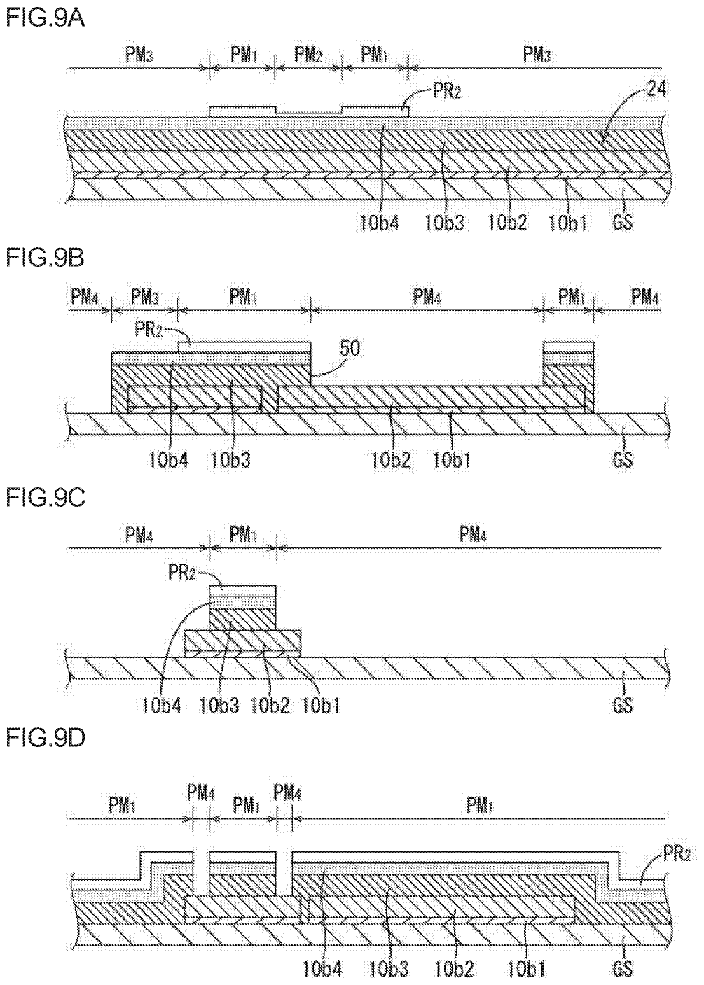

The photoresist film is exposed through the second photomask PM and the exposed photoresist film is developed, and after the exposed sections are removed, a photoresist film PR₁ illustrated in FIG. 8 is obtained. Namely, the photoresist with its original film thickness remains on the unexposed sections corresponding to the first sections PM₁. The photoresist is completely removed from the exposed sections corresponding to the fourth section PM₄. The photoresist with film thickness corresponding to the light transmittance remains on intermediate exposed sections corresponding to the second section PM₂ and the third section PM₃. The photoresist film PR₁ is formed to have a greater thickness as the section corresponds to the section having lower light transmittance. If the first insulating film 10b3 and the semiconductor film 10b4 are etched using the patterned photoresist film PR₁ as the etching mask, as illustrated in FIG. 9, the sections that correspond to the fourth sections PM₄ and are not overlapped with the photoresist film PR₁ are removed by etching and the sections corresponding to the three sections PM₁, PM₂, and PM₃ overlapping the photoresist film PR₁ remain.

As illustrated n FIG. 9B, through the photoresist forming step and the first insulating film/semiconductor film etching step, most portions of the pixel electrode sections 21a are exposed. Namely, a hole 50 for exposing the pixel electrode 21 is formed. Therefore, in the method of producing the array substrate 10b in this embodiment, a hole forming step includes the photoresist forming step and the first insulating film/semiconductor film etching step.

In the ashing step that is performed after the first insulating film/semiconductor film etching step, a portion of the photoresist film PR₁ is removed by ashing (development). Specifically, the photoresist film PR₁ is removed such that the portions of the photoresist corresponding to the third sections PM₃ having a smallest film thickness are removed and only the portions of the photoresist corresponding to the first sections PM₁ and the second sections PM₂ remain. Accordingly, a photoresist film PR₂ illustrated in FIG. 9 is obtained.

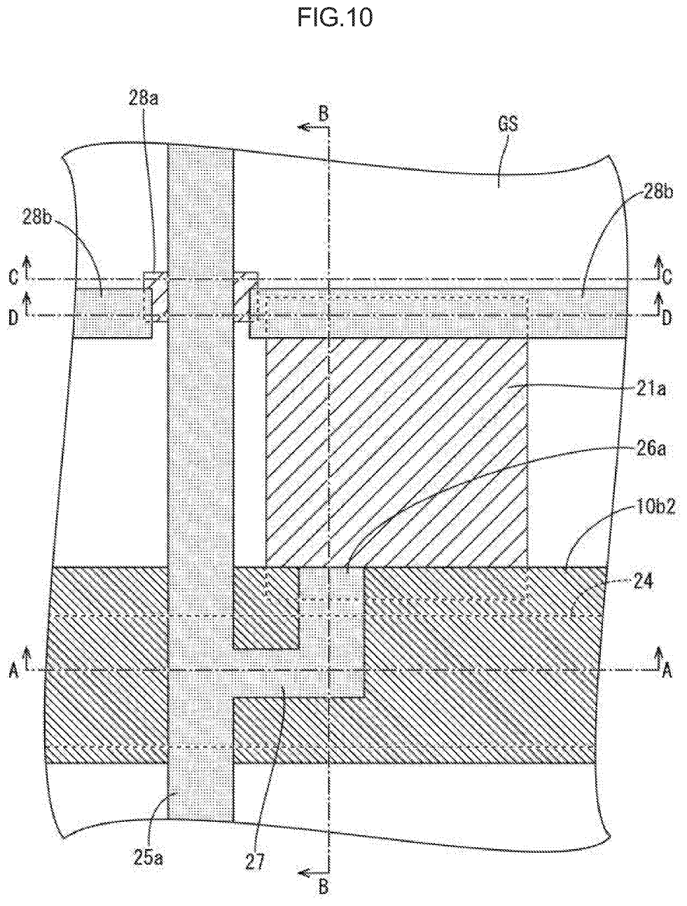

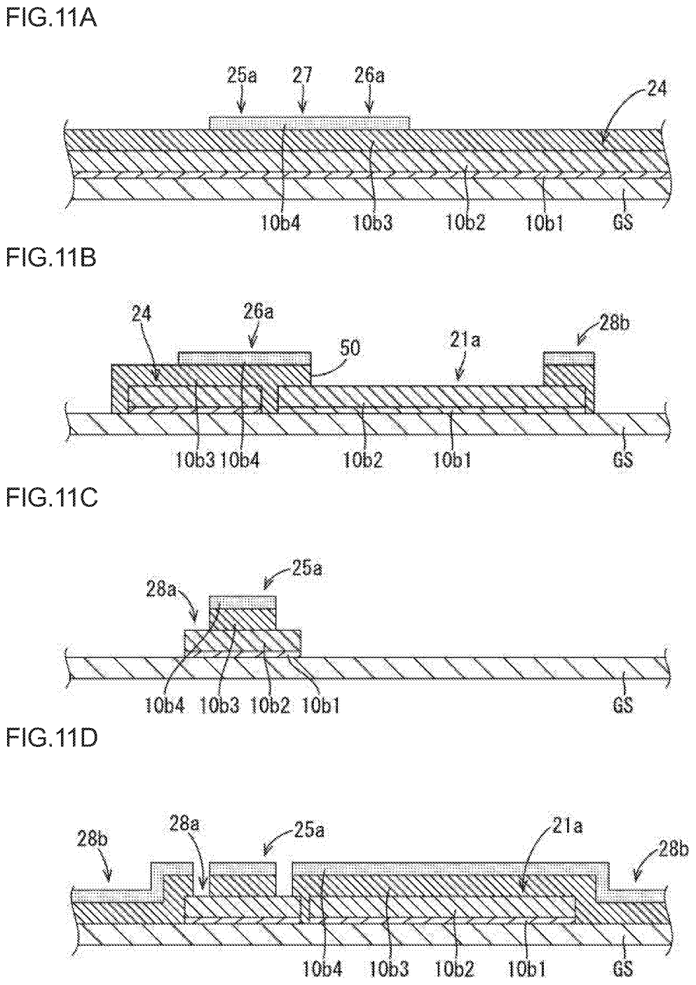

If the semiconductor film 10b4 on the first insulating film 10b3 is etched while using the photoresist film PR₂ as the etching mask, as illustrated in FIGS. 10 and 11, the portions that correspond to the third section PM₃ and are not overlapped with the photoresist film PR₂ are removed by etching and the portions that correspond to the first sections PM₁ and the second sections PM₂ and overlap the photoresist film PR₂ remain. Accordingly, on the first insulating film 10b3, as the sections of the semiconductor film 10b4, the channel sections 27, the semiconductor source sections 25a, the semiconductor drain sections 26a, and the semiconductor capacitance line sections 28b are formed. The channel sections 27 overlap the gate lines 24 while having the first insulating film 10b3 therebetween. The semiconductor source section 25a is connected to one end (a left side in FIG. 10) of the channel section 27 with respect to the X-axis direction and extends in the Y-axis direction. The semiconductor drain section 26a is connected to another end of the channel section 27 with respect to the X-axis direction and extends in the Y-axis direction. The semiconductor capacitance line section 28b is overlapped with the pixel electrode section 21a at a portion thereof opposite from the gate line 24 with respect to the pixel electrode section 21a in the Y-axis direction. As described earlier, in the method of producing the array substrate 10b in this embodiment, a semiconductor film patterning step includes the ashing step and the semiconductor film etching step. In the second photolithography process, it can be considered that the second photomask PM functions as the photomask illustrated in FIG. 7B. More in detail, the second photomask PM includes a first section A₁, a second section A₂, and a third section A₃. The first section A₁ corresponds to an exposure section for forming the resist pattern for removing the first insulating film 10b3 and the semiconductor film 10b4. The second section A₂ corresponds to an intermediate exposure section for forming the resist pattern for removing the semiconductor film 10b4 and keeping the first insulating film 10b3. The third section A₃ corresponds to an unexposed section for forming the resist pattern for keeping the first insulating film 10b3 and the semiconductor film 10b4.

(iii) Pixel Electrode Forming Process

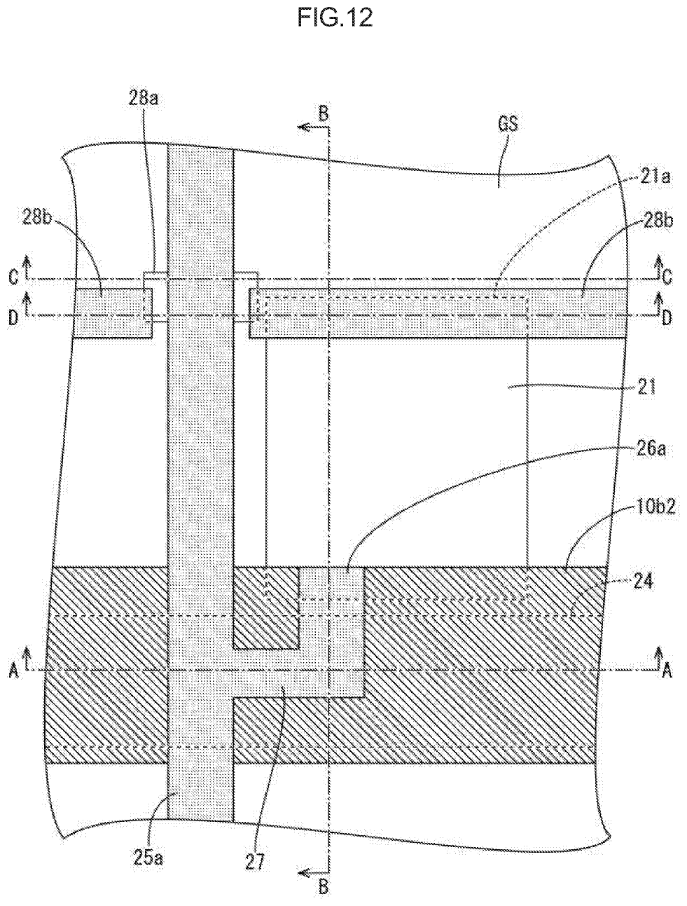

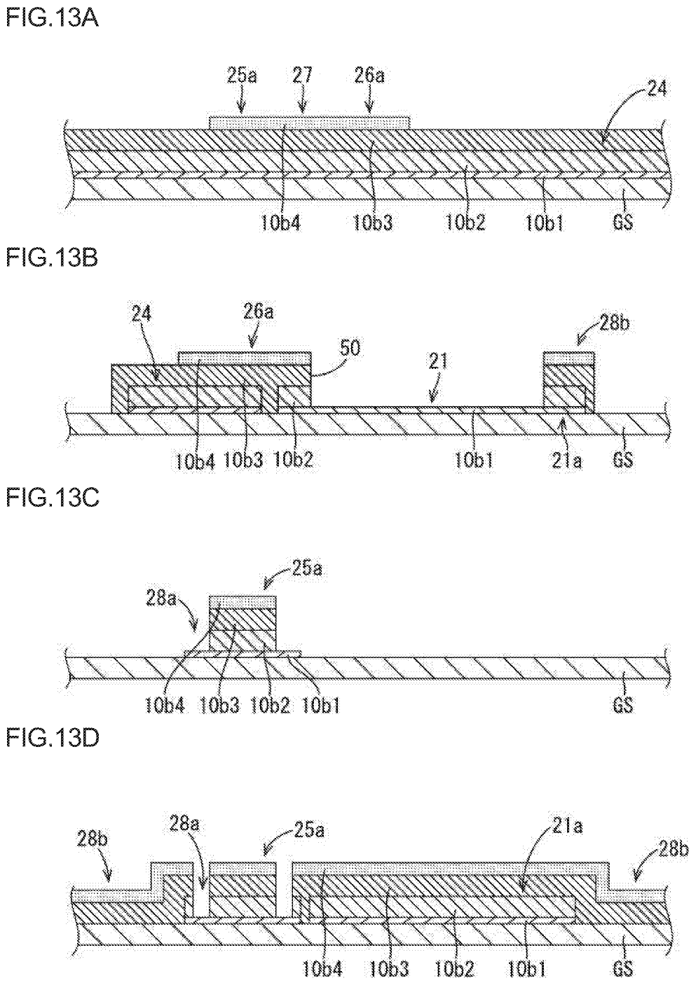

Next, the first metal film 10b2 is etched while using the first insulating film 10b3 and the semiconductor film 10b4, which are formed as described earlier, as the etching mask. More in detail, out of the transparent conductive film 10b1 and the first metal film 10b2 that are disposed on top of each other, only the first metal film 10b2 is etched and the transparent conductive film 10b1 remains. Accordingly, as illustrated in FIGS. 12 and 13B, a portion of the pixel electrode section 21a, which is a section of the transparent conductive film 10b1, is exposed through the hole 50 to form the pixel electrode 21.

(iv) Third Photolithography Process

Next, the third photolithography process is performed and the third photolithography process includes a second metal film forming step, a photoresist forming step, an ashing step, and a second metal film etching step. The second metal film forming step is for forming the second metal film 10b5 on the semiconductor film 10b4. The photoresist forming step is for exposing and developing the photoresist film using the second photomask PM and patterning the photoresist film on the second metal film 10b5. The ashing step is for removing a portion of the patterned photoresist film by ashing. The second metal film etching step is for etching the second metal film 10b5 using the photoresist film with ashing as the etching mask.

In the third photolithography process, the second metal film 10b5 is formed through the second metal film forming step. Subsequently, in the photoresist forming step, the photoresist film is disposed on the second metal film 10b5 and the photoresist film is exposed and developed while using the second photomask PM that was used in the second photolithography step to be patterned. The photoresist film is exposed at a position that is displaced in the Y-axis direction from the exposed position of the photoresist film in the second photolithography process. If the photoresist film that is exposed using the second photomask PM is developed and the exposed portion is removed, the photoresist is completely removed from the exposed sections corresponding to the fourth section PM₄ similarly to the photoresist forming step in the second photolithography process. On unexposed sections corresponding to the first sections PM₁, intermediate exposed sections corresponding to the second section PM₂ and the third section PM₃, a film thickness of the photoresist increases as the light transmittance of the corresponding section is lowered.

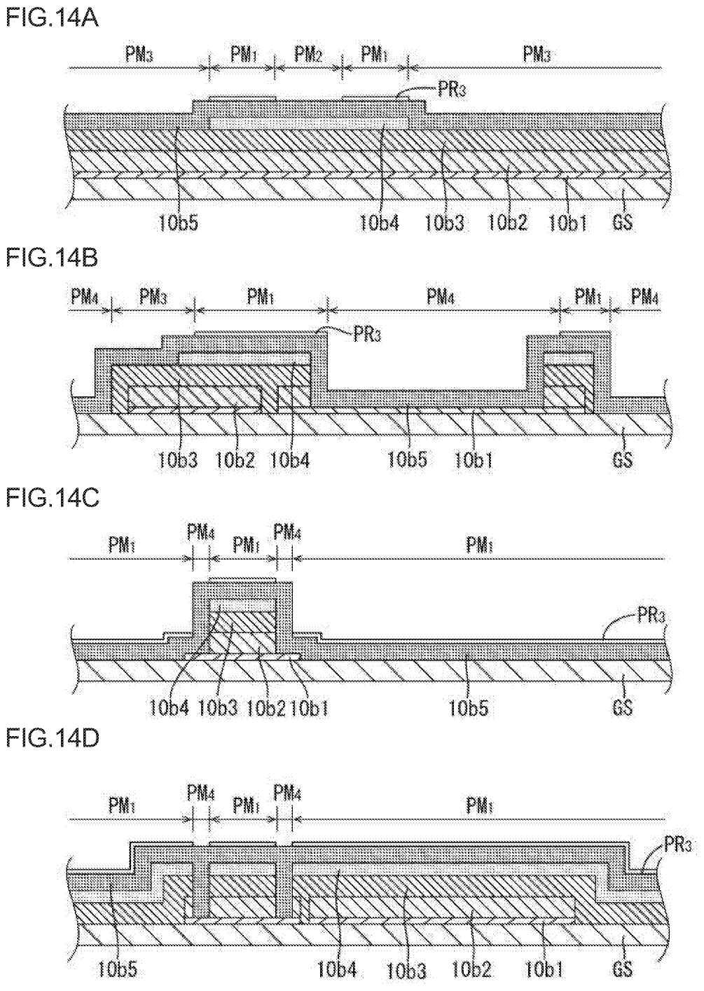

Next, a portion of the photoresist film PR₃ is removed by ashing (developing). Specifically, the photoresist film PR₃ is removed by ashing such that the portions of the photoresist corresponding to the third sections PM₃ having a small film thickness and the portions corresponding to the second sections PM₂ are removed and only the portions of the photoresist corresponding to the first sections PM₁ remain. Accordingly, a photoresist film PR₂ illustrated in FIG. 14 is obtained.

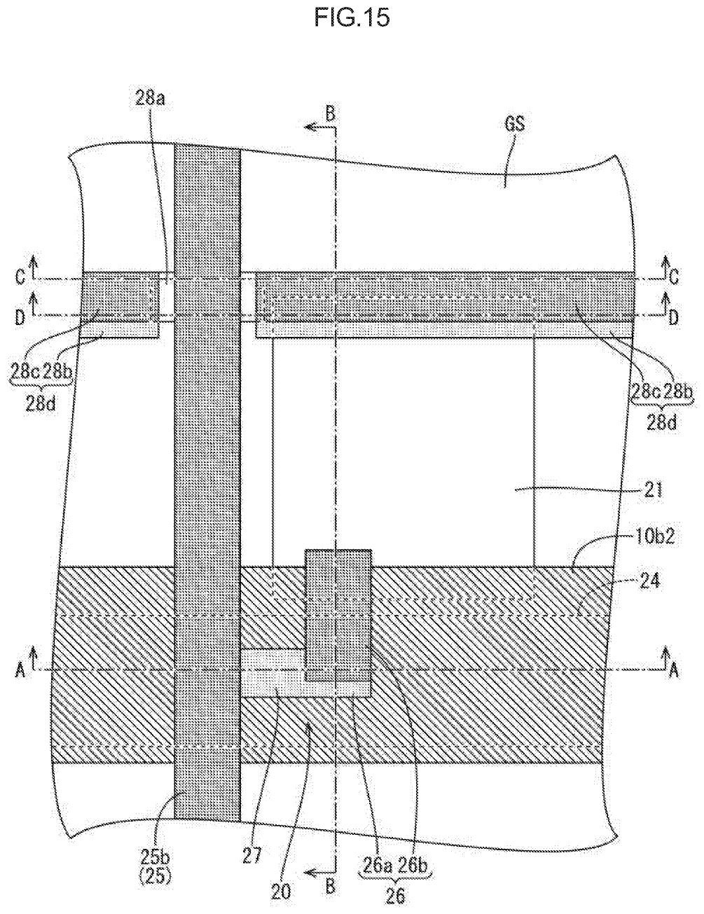

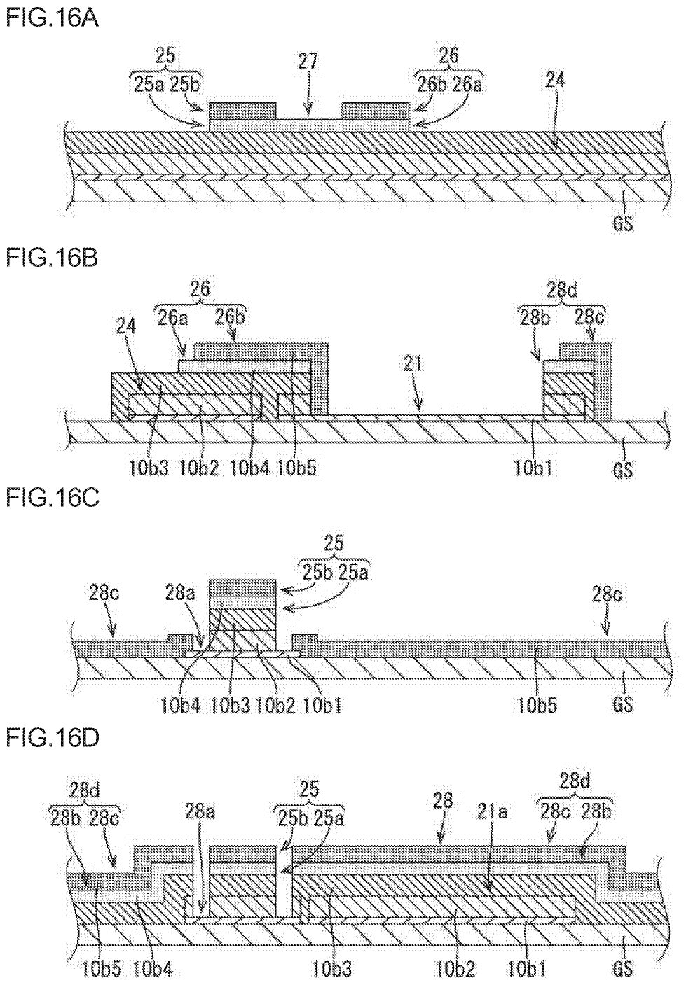

If the second metal film 10b5 is etched while using the photoresist film PR₃ as the etching mask, as illustrated in FIGS. 15 and 16, the portions that correspond to the second section PM₂, the third section PM₃, and the fourth section PM₄ and are not overlapped with the photoresist film PR₃ are removed by etching and only the portions that correspond to the first sections PM₁ and overlap the photoresist film PR₃ remain. Accordingly, as the sections of the second metal film 10b5, the metal source sections 25b that overlap the semiconductor source sections 25a, the metal drain sections 26b that overlap the semiconductor drain sections 26a with being displaced in the Y-axis direction, and the metal capacitance line sections 28c that overlap the semiconductor capacitance line sections 28b with being displaced in the Y-axis direction are formed. As illustrated in FIG. 15, the metal drain section 26b is displaced from the semiconductor drain section 26a in the Y-axis direction. The metal drain section 26b projects from the semiconductor drain section 26a toward the pixel electrode 21. As illustrated in FIG. 16B, one end of the metal drain section 26b is connected to the pixel electrode 21. The metal capacitance line section 28c overlaps the semiconductor capacitance line section 28b and the semiconductor capacitance line section 28b and the metal capacitance line section 28c configure a capacitance line section 28d. As illustrated in FIG. 15, the metal capacitance line section 28c is displaced from the semiconductor capacitance line section 28b in the Y-axis direction so that the capacitance line section 28d is connected to the capacitance line connecting section 28a. As described earlier, in the method of producing the array substrate 10b in this embodiment, a metal film patterning step includes the photoresist forming step, the ashing step, and the semiconductor film etching step of the third photolithography process. In the third photolithography process, it can be considered that the second photomask PM functions as the photomask illustrated in FIG. 7C. More in detail, the second photomask PM includes a fourth section A₄ and a fifth section A₅. The fourth section A₄ corresponds to an exposure section for forming the resist pattern for removing the second metal film 10b5. The fifth section A₅ corresponds to an unexposed section for forming the resist pattern for keeping the second metal film 10b5.

(v) Second Insulating Film Forming Process and Alignment Film Forming Process

Subsequently, as illustrated in FIG. 4, the second insulating film 10b6 is formed through the second insulating film forming process and the alignment film 22 is formed through the alignment film forming process and then, the array substrate 10b is obtained.

According to the producing method described earlier, the array substrate 10b in this embodiment includes the pixel electrode 21, the first insulating film 10b3, the channel section 27, the source electrode 25, and the drain electrode 26. The pixel electrode 21 is a section of the transparent conductive film 10b1, which is the conductive film. The first insulating film 10b3 is included in a layer upper than the transparent conductive film 10b1 and formed to expose the pixel electrode 21. The channel section 27 is included in the TFT 20, which is the thin film transistor, and is a section of the semiconductor film 10b4 that is disposed on the first insulating film 10b3. The source electrode 25 is included in the TFT 20 and includes (a-1) the semiconductor source section 25a and (a-2) the metal source section 25b that are disposed on top of each other. The semiconductor source section 25a is a section of the semiconductor film 10b4 and is connected to one end of the channel section 27. The metal source section 25b is a section of the second metal film 10b5 that is included in a layer upper than the semiconductor film 10b4. The drain electrode 26 is included in the TFT 20 and includes (b-1) the semiconductor drain section 26a and (b-2) the metal drain section 26b that are disposed on top of each other. The semiconductor drain section 26a is a section of the semiconductor film 10b4 and is connected to another end of the channel section 27. The metal drain section 26b is a section of the second metal film 10b5. The metal drain section 26b overlaps the semiconductor drain section 26a and extends from the semiconductor drain section 26a so as to overlap the pixel electrode 21 and to be connected to the pixel electrode 21.

According to such a configuration, in the array substrate 10b of this embodiment, as the producing method thereof is described earlier, the first insulating film 10b3, the semiconductor film 10b4, and the second metal film 10b5 are patterned with one photomask (the second photomask PM). The number of photomasks can be reduced and also the number of the photolithography processes can be reduced since the first insulating film 10b3 and the semiconductor film 10b4 can be patterned in one photolithography process (the second photolithography process). Accordingly, with such an array substrate 10b, a producing cost and the number of producing processes can be reduced. Further, if using a number of photomasks, unevenness may be caused in finishing precision of the substrates. However, with the array substrate 10b, the number of photomasks is small and therefore, the finishing precision can be improved and the array substrate 10b is preferably used for an array substrate with high resolution. Further, the array substrate 10b does not include a contact hole for connecting the pixel electrode 21 and the drain electrode 26. Therefore, connection errors are less likely to be caused by filling of contact holes.

In the present embodiment, the conductive film has a single-layer structure of the transparent conductive film 10b1 but may have a multi-layer structure of the transparent conductive film and a metal film (metal mesh). With such a configuration, a resistance of the pixel electrode can be reduced. The second metal film 10b5 may also have a multi-layer structure including two or more layers. If including a corrosion resistant metal material in the most upper layer, the metal film has a configuration that the second insulation film 10b6 is removed.

The array substrate 10b in the present embodiment includes the gate line 24. The gate line 24 includes (c-1) a section of the transparent conductive film 10b1 and (c-2) the metal film 10b2 that are disposed on top of each other and the gate line 24 is covered with the first insulating film 10b3. The first metal film 10b2 is disposed between the transparent conductive film 10b1 and the first insulating film 10b3 and is a lower layer side metal film, which is a metal film different from the second metal film 10b5.

According to such a configuration, after the transparent conductive film 10b1 and the first metal film 10b2 are disposed on top of each other, the films are etched so that the pixel electrode section 21a including the gate line 24 and the pixel electrode 21 can be formed. Then, above the films, the first insulating film 10b3 and the semiconductor film 10b4 are formed and patterned so that the gate line 24 is covered with the first insulating film 10b3 and a portion of the pixel electrode section 21a is uncovered. As described earlier, only the portion of the first metal film 10b2 corresponding to the portion of the pixel electrode section 21a is removed and the transparent conductive film 10b1 remains while using the portions of the first insulating film 10b3 and the semiconductor film 10b4 as the etching mask. Thus, the pixel electrode 21 is obtained. Namely, in the array substrate 10b, the transparent conductive film 10b1 and the first metal film 10b2 can be patterned with one photomask (the first photomask). Therefore, the array substrate 10b can be produced with only two photomasks of the first photomask and the second photomask that is a multi-gradation mask and used for patterning the first insulating film 10b3, the semiconductor film 10b4, and the second metal film 10b5.

The array substrate 10b in the present embodiment includes the auxiliary capacitance line 28 for keeping the potential of the pixel electrode 21. The auxiliary capacitance line 28 includes the capacitance line section 28d as a main section. The capacitance line section 28d includes the semiconductor capacitance line section 28b and the metal capacitance line section 28c that are disposed on top of each other. The semiconductor capacitance line section 28b is a section of the semiconductor film 10b4 and is overlapped with the partial pixel electrode section 21a, which functions as the pixel electrode 21, via the first insulating film 10b3. The metal capacitance line section 28c is a section of the second metal film 10b5. A displacement of the metal capacitance line section 28c with respect to the semiconductor capacitance line section 28b is equal to a displacement of the metal drain section 26b with respect to the semiconductor drain section 26a.

In the array substrate 10b of the present embodiment, the auxiliary capacitance line 28 includes the source line crossing section 28a (the capacitance line connecting section) and the capacitance line connecting section 28a and the metal capacitance line section 28c are connected to each other. The capacitance line connecting section 28a is included in a layer lower than the first insulating film 10b3 and included at a portion of the first insulating film 10b3 where the source line 25 is formed. The capacitance line connecting section 28a is at least a part of the transparent conductive film 10b1 and crosses the source line 25.

According to such a configuration, the array substrate 10b including the auxiliary capacitance line 28 can be produced with only two photomasks that are necessary for forming the TFTs 20.

In the array substrate 10b of the present embodiment, the drain electrode 26 extends in parallel to the source line 25. In producing the array substrate 10b, the position of the second photomask in the third photolithography process is moved in parallel to the source line 25 (in the Y-axis direction) from the position thereof in the second photolithography process. Accordingly, the semiconductor source section 25a and the metal source section 25b included in the source line 25 can be overlapped with each other without causing displacement. The semiconductor drain section 26a and the metal drain section 26b included in the drain electrode 26 are substantially overlapped with each other without causing displacement in the X-axis direction.

In the array substrate 10b of the present embodiment, the first insulating film 10b3 overlaps the pixel electrode section 21a including a section that functions as the pixel electrode 21 and the metal drain section 26b extends from the section of the first insulating film 10b3 that overlaps the pixel electrode section 21a so as to overlap the pixel electrode 21. According to such a configuration, the drain electrode 26 can be connected to the pixel electrode 21 surely in the array substrate 10b.

### Modified Embodiment 1

In the array substrate 10b of the above embodiment, the metal drain section 26b is directly connected to the pixel electrode 21 (the transparent conductive film 10b1). However, the metal drain section 26b may be connected to the transparent conductive film 10b1 via the first metal film 10b2 so as to be connected to the pixel electrode 21. With a plan view (refer FIG. 3), the array substrate of the modified embodiment is similar to the array substrate 10b of the above embodiment. For the array substrate of the modified embodiment, a producing method and a configuration thereof will be described.

The processes of the method of producing the array substrate of the modified embodiment are similar to the processes until the second photolithography process described earlier. After the second photolithography method, the pixel electrode forming process is performed in the method of producing the array substrate in the above embodiment; however, the second metal film 10b5 is formed in the method of producing the array substrate of the modified embodiment.

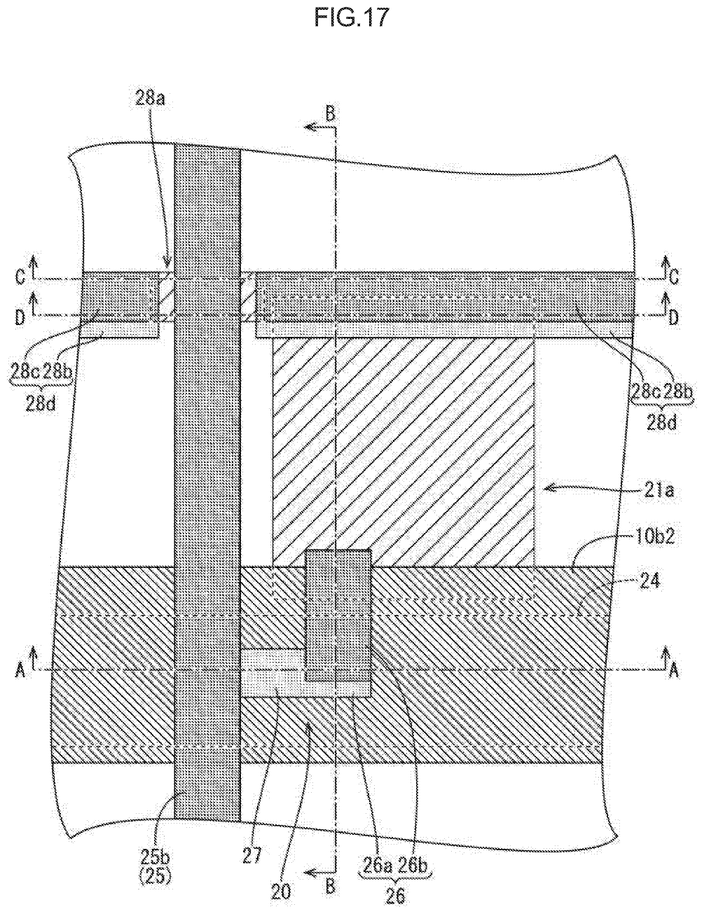

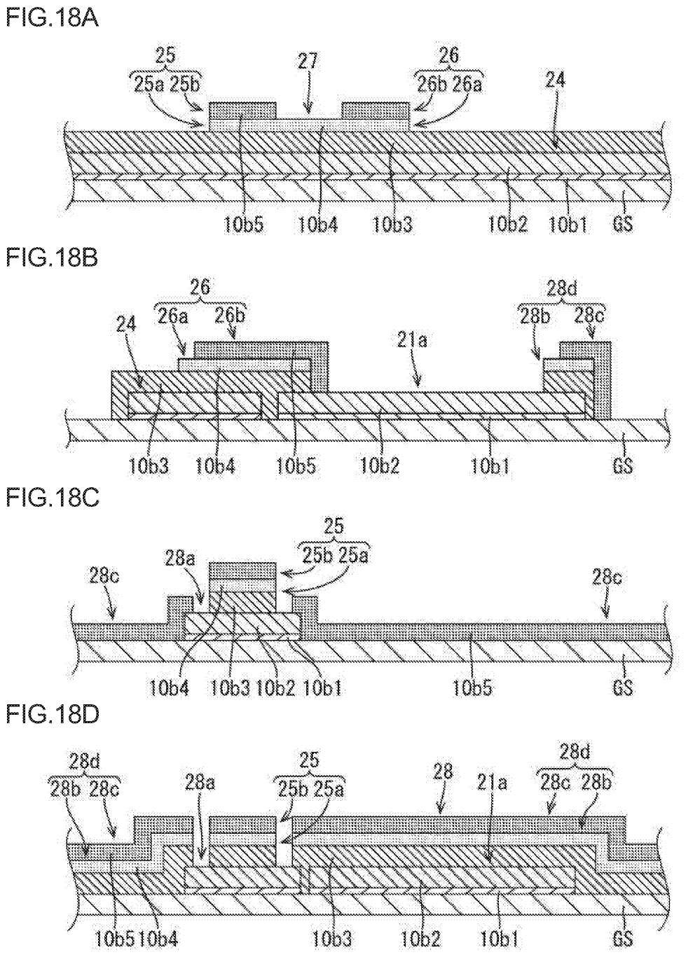

FIGS. 17 and 18 illustrate the substrate where the second metal film 10b5 is patterned after the second photolithography process in the method of producing the array substrate of the modified embodiment. With such a method, as illustrated in FIG. 18B, the metal drain section 26b is disposed on the first metal film 10b2 section of the pixel electrode section 21a since the first metal film 10b2 section included in the pixel electrode section 21a is not etched yet. Similarly, since the first metal film 10b2 section of the capacitance line connecting section 28 is not etched yet, one end of the metal capacitance line section 28c is disposed on the first metal film 10b2 section of the capacitance line connecting section 28a.

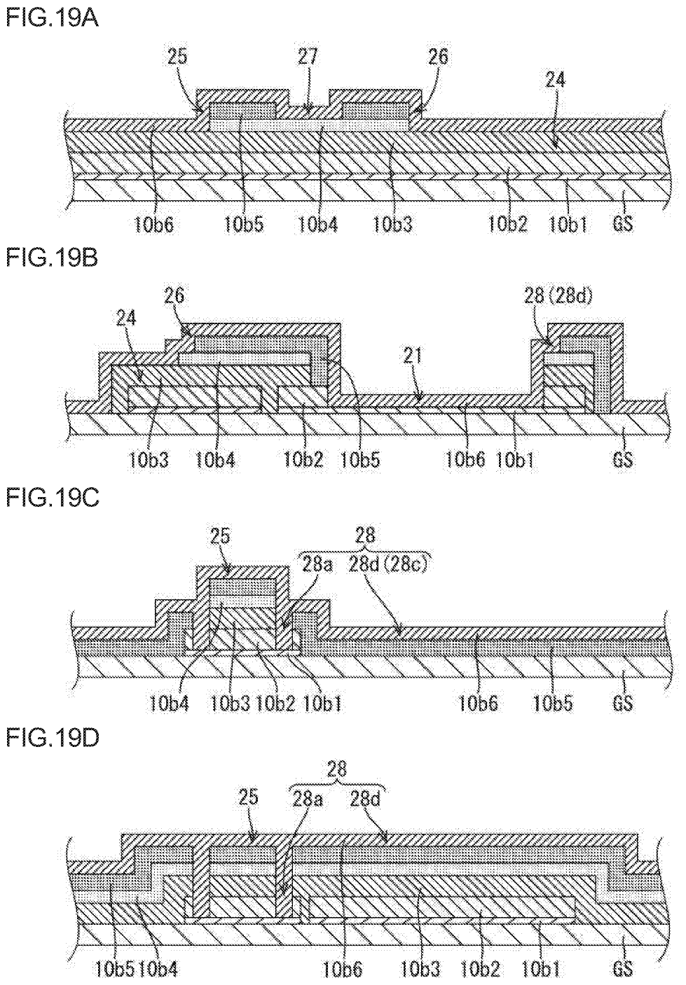

The first metal film 10b2 is etched while using the first insulating film 10b3, the semiconductor film 10b4, and the second metal film 10b5 as the etching mask. As illustrated in FIGS. 3 and 19, the portion of the transparent conductive film 10b1 included in the pixel electrode section 21a is exposed through the hole 50 and the pixel electrode 21 is formed.

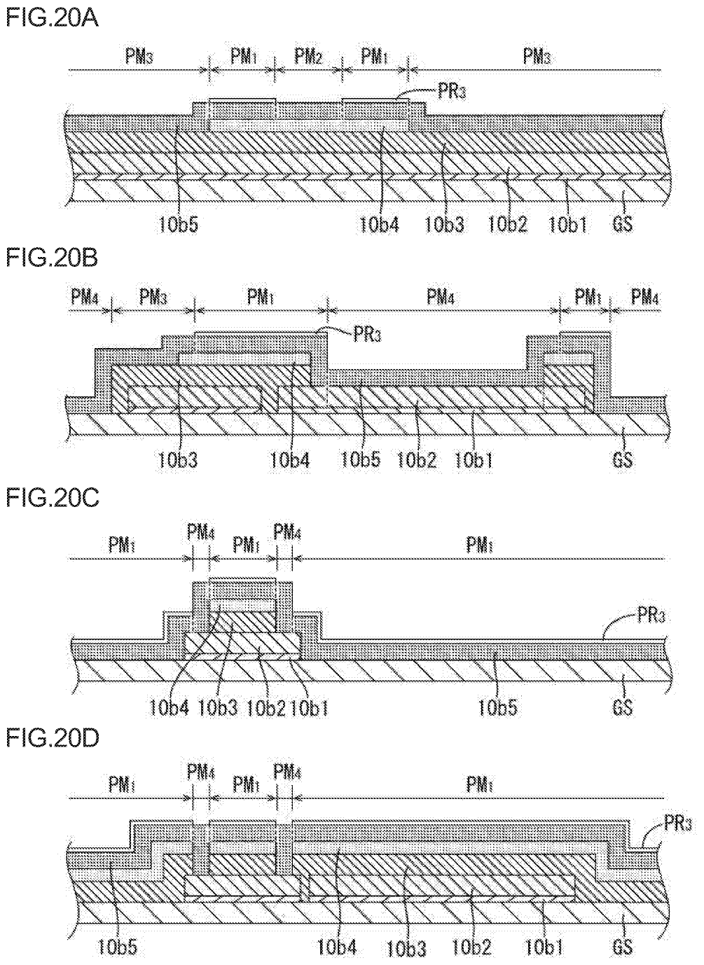

As illustrated in FIG. 20, the second metal film 10b5 may be formed after the second photolithography process and the first metal film 10b2 and the second metal film 10b5 may be etched at the same time. More in detail, after the second metal film 10b5 is formed, the photoresist film PR₃ that is formed by patterning-ashing in the third photolithography process in the above embodiment is formed. The second metal film 10b5 and the first metal film 10b2 are etched while using the photoresist film PR₃ as an etching mask. Namely, in the array substrate having the above configuration according to the modified embodiment, the number of etching processes can be reduced.

### Other Embodiments

In the above embodiment, the array substrate is included in the liquid crystal panel 10 that operates in the VA mode; however the operation mode is not limited thereto. The image display mechanism and the operation mode of the liquid crystal panel are not particularly limited. The present technology can be applied to array substrates included in the liquid crystal panels that operate in various operation modes such as an IPS mode and a FFS mode. The present technology is not limited to the liquid crystal panel but may be applied to a substrate included in an in-cell touch panel type display panel.

1. A thin film transistor substrate including a thin film transistor, the thin film transistor substrate comprising:
a pixel electrode that is a section of a conductive film;
an insulating film disposed in a layer upper than the conductive film and formed to expose the pixel electrode;
a channel section that is a section of a semiconductor film disposed on the insulating film and that is included in the thin film transistor;
a source electrode included in the thin film transistor and including (a-1) a semiconductor source section that is a section of the semiconductor film and connected to one end of the channel section and (a-2) a metal source section that is a section of a metal film disposed in a layer upper than the semiconductor film, the semiconductor source section and the metal source section being disposed on top of each other; and
a drain electrode included in the thin film transistor and including (b-1) a semiconductor drain section that is a section of the semiconductor film and connected to another end of the channel section and (b-2) a metal drain section that is a section of the metal film and overlaps the semiconductor drain section and extends from the semiconductor drain section so as to overlap the pixel electrode and is connected to the pixel electrode.

2. The thin film transistor substrate according to claim 1, further comprising a gate line including (c-1) a section of the conductive film and (c-2) a lower layer side metal film that is a metal film different from the metal film disposed between the conductive film and the insulating film, the section of the conductive film and the lower layer side metal film being disposed on top of each other, and the gate line being covered with the insulating film.

3. The thin film transistor substrate according to claim 2, wherein the metal drain section is connected to the conductive film via the lower layer side metal film so as to be connected to the pixel electrode.

4. The thin film transistor substrate according to claim 1, further comprising:
an auxiliary capacitance line for keeping a potential of the pixel electrode, the auxiliary capacitance line including a capacitance line section including (d-1) a semiconductor capacitance line section that is a section of the semiconductor film overlapped with the conductive film including the section functioning as the pixel electrode on an upper layer side via the insulating film and (d-2) a metal capacitance line section that is a section of the metal film, the semiconductor capacitance line section and the metal capacitance line section being disposed on top of each other, wherein
a displacement of the metal capacitance line section with respect to the semiconductor capacitance line section is equal to a displacement of the metal drain section with respect to the semiconductor drain section.

5. The thin film transistor substrate according to claim 4, further comprising a source line including a section of the semiconductor film and a section of the metal film that are disposed on top of each other on the insulating film, the source line being connected to the source electrode, wherein
the auxiliary capacitance line includes a source line crossing section that is disposed in a layer lower than the insulating film and corresponding to a section where the source line is disposed, the source line crossing section is a section of the conductive film and formed to cross the source line, and the auxiliary capacitance line is configured by connecting the source line crossing section and the metal capacitance line section.

6. The thin film transistor substrate according to claim 1, further comprising a source line including a section of the semiconductor film and a section of the metal film that are disposed on top of each other on the insulating film, the source line being connected to the source electrode, wherein
the drain electrode extends in parallel to the source line.

7. The thin film transistor substrate according to claim 1, wherein
the insulating film overlaps a section of the conductive film including a section that functions as the pixel electrode, and
the metal drain section extends from a section of the insulating film overlapping a section of the conductive film and overlaps the pixel electrode.

8. A method of producing a thin film transistor substrate including a thin film transistor, the method comprising:
a conductive film forming step of forming a conductive film;
an insulating film forming step of forming an insulating film in a layer upper than the conductive film;
a semiconductor film forming step of forming a semiconductor film in a layer upper than the insulating film;
a hole forming step of forming a hole through which a section of the conductive film is exposed as a pixel electrode by patterning a photoresist film in a predetermined form on the semiconductor film while using a multi-gradation mask including sections having different light transmittance and etching portions of the insulation film and the semiconductor film while using a patterned photoresist film as an etching mask;
a semiconductor film patterning step of developing and removing a portion of the photoresist film that is patterned in the hole forming step and etching a portion of the semiconductor film while using the photoresist film a portion of which is removed as an etching mask to provide a channel section, a semiconductor source section connected to one end of the channel section, and a semiconductor drain section connected to another end of the channel section from the semiconductor film;
a metal film forming step of forming a metal film disposed in a layer upper than the semiconductor film after the semiconductor film patterning step; and
a metal film patterning step of patterning a photoresist film in a predetermined form on the metal film while using the multi-gradation mask in a position different from a position used in the hole forming step and etching a portion of the metal film while using a patterned photoresist film as an etching mask to provide a source electrode by disposing a metal source section in a layer upper than the semiconductor source section and provide a drain electrode by disposing a metal drain section in a layer upper than the semiconductor drain section while being displaced from the semiconductor drain section such that one end of the metal drain section projects toward the hole and overlaps a section of the conductive film.

9. The method of producing the thin film transistor substrate according to claim 8, wherein the multi-gradation mask includes a section corresponding to the semiconductor source section and the semiconductor drain section, a section corresponding to the channel section, a section for keeping only the insulating film, and a section for removing the insulating film and the semiconductor film, and each of the sections has different light transmittance.

10. The method of producing the thin film transistor substrate according to claim 8, further comprising:
a lower layer side metal film forming step of forming a lower layer side metal film in a layer upper than the conductive film;
a conductive film/lower layer metal film etching step of etching portions of the conductive film and the lower layer side metal film to provide a pixel electrode section including the pixel electrode and a gate line; and
a pixel electrode forming step of etching the lower layer side metal film included in the pixel electrode section while using a section disposed in a layer upper than the insulating film as a matching mask to keep the conductive film and expose a section of the conductive film through the hole and providing the pixel electrode.
